(19) United States
(12) Patent Application Publication
(10) Pub. No.: US 2025/0006713 A1
(43) Pub. Date: Jan. 2, 2025

(54) HIGH VOLTAGE POWER TRANSFER ON PRINTED CIRCUIT BOARD

(71) Applicant: Intel Corporation, Santa Clara, CA (US)

(72) Inventors: Bharath Reddy GUDIGOPURAM, Nalgonda (IN); Ajmeer Kaja AYUBKHAN, Bangalore (IN); Siva Prasad JANGILI GANGA, Jagityal Dist (IN)

(21) Appl. No.: 18/343,770

(22) Filed: Jun. 29, 2023

(51) Int. Cl. H01L 25/10; H01L 25/00; H01L 25/16

(52) U.S. Cl. CPC H01L 25/105; H01L 25/16; H01L 25/50; H01L 24/16; H01L 24/17; H01L 2224/16145; H01L 2224/16225; H01L 2224/17181; H02M 1/14; H02M 3/003

(57) ABSTRACT

Disclosed herein is a device that provides for high power transfer. The device may include a printed circuit board and a package substrate disposed on the printed circuit board. The device may also include a plurality of high-power voltage regulators disposed on and electrically connected to the package substrate. The device may also include a plurality of low-power voltage regulators disposed on and electrically connected to the printed circuit board.

### BACKGROUND

Conventional printed circuit boards (PCB) operate using low voltages, which draw a lot of current for a certain amount of power. This in turn increases power loss and many planes are required to reduce the resistance, which leads to an increase in the number of PCB planes.

There is a need to reduce the power loss on PCB as well as reduced the number of planes required.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows a cross-sectional view of a semiconductor device according to an aspect of the present disclosure;

FIG. 2 shows a flow chart illustrating a method of forming a semiconductor device according to an aspect of the present disclosure;

FIG. 3 shows a power loss table of a semiconductor device according to an aspect of the present disclosure; and

FIG. 4 shows an illustration of a computing device that includes a semiconductor device according to a further aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for the present devices, and various aspects are provided for the methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

An advantage of the present disclosure may include reduced complexity of the PCB as the high power voltage regulator is removed on the PCB for the high current rails and is placed on the package substrate instead. Power is routed to the high-power voltage regulator before being routed to the base die and the top die. This minimizes power loss, and minimizes the number of layers or routing lengths on the PCB to meet the same performance. Further, the heat sink design on the PCB will be simpler, and capacitors on the PCB can be removed or reduced, which reduces the cost and complexity of the PCB.

These and other aforementioned advantages and features of the aspects herein disclosed will be apparent through reference to the following description and the accompanying drawings. Furthermore, it is to be understood that the features of the various aspects described herein are not mutually exclusive and can exist in various combinations and permutations.

The present disclosure generally relates to a device. The device may include a printed circuit board. The device may also include a package substrate disposed on the printed circuit board. The device may also include a plurality of high-power voltage regulators disposed on and electrically connected to the package substrate. The device may also include a plurality of low-power voltage regulators disposed on and electrically connected to the printed circuit board. There may be 5-10 low-power voltage regulators disposed on and electrically connected to the printed circuit board.

The present disclosure generally relates to a method of forming a device. The method may include providing a printed circuit board. The method may also include disposing a package substrate on the printed circuit board. The method may also include disposing and electrically connecting a plurality of high-power voltage regulators to the package substrate. The method may also include disposing and electrically connecting a plurality of low-power voltage regulators to the printed circuit board. There may be 5-10 high-power voltage regulators disposed on and electrically connected to the printed circuit board.

To more readily understand and put into practical effect, the present device, method, and other particular aspects will now be described by way of examples and not limitations, and with reference to the figures. For the sake of brevity, duplicate descriptions of features and properties may be omitted.

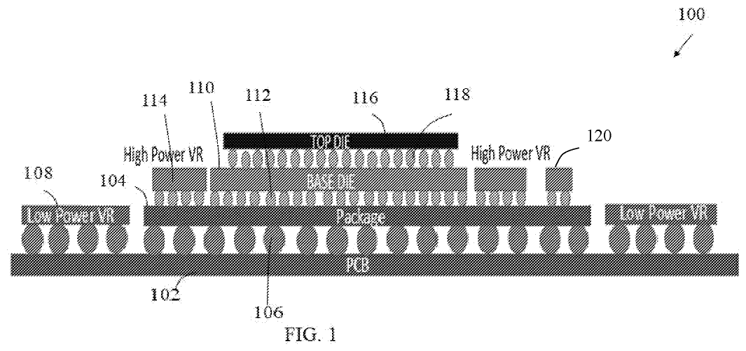

FIG. 1 shows a cross-sectional view of a semiconductor device according to an aspect of the present disclosure.

In an aspect of the present disclosure, a semiconductor device 100 is shown in FIG. 1. The semiconductor device 100 may be a stacked semiconductor package like a 2.5D or a 3D semiconductor package.

In an aspect of the present disclosure, the semiconductor device 100 may include a printed circuit board (PCB) 102. The printed circuit board 102 may be a motherboard.

In an aspect of the present disclosure, the semiconductor device 100 may include a package substrate 104. The package substrate 104 may include contact pads, electrical interconnects, routings, and other features, which are not shown in any of the present figures. The package substrate 104 may have one or more rigid core layers for improved structural stability or a coreless substrate package for a reduced form factor. In other aspects, the package substrate 104 may be part of a larger substrate that supports additional semiconductor packages, and/or components.

In an aspect of the present disclosure, the semiconductor device 100 may include a plurality of solder balls 106. In an aspect, the plurality of solder balls 106 may be disposed on a bottom surface of the package substrate 104. The package substrate 104 may be disposed on and electrically connected to the printed circuit board 102 through the plurality of solder balls 106. In an aspect, the plurality of solder balls 106 may provide an electrical connection between the package substrate 104, and the printed circuit board 102.

In an aspect of the present disclosure, the semiconductor device 100 may include a plurality of low power voltage regulators (VR) 108. The plurality of low power voltage regulators 108 may be disposed on and electrically connected to the printed circuit board 102 through the plurality of solder balls 106. In an aspect, the plurality of low power voltage regulators 108 is positioned adjacent to the package substrate 104. Each low power voltage regulator of the plurality of low power voltage regulators 108 may operate between 0.6V to 3.3V.

In an aspect of the present disclosure, the semiconductor device 100 may include a base die 110. In an aspect, the base die 110 may be made from any suitable semiconductor, such as silicon or gallium arsenide. The base die 110 may be a semiconductor die, a chip, or a set of chiplets, e.g., a system-on-chip (SOC), a platform controller hub (PCH)/chipset, a memory device, a field programmable gate array (FPGA) device, a central processing unit (CPU), or a graphic processing unit (GPU).

In an aspect of the present disclosure, the semiconductor device 100 may include a plurality of package bumps 112. The plurality of package bumps 112 may be disposed between the package substrate 104 and the base die 110. In an aspect, the plurality of package bumps 112 may facilitate an electrical connection between the base die 110 and the package substrate 104.

In an aspect of the present disclosure, the semiconductor device 100 may include a plurality of high power voltage regulators (VR) 114. The plurality of high-power voltage regulators 114 may be disposed on and electrically connected to the package substrate 104 through the plurality of package bumps 112. In an aspect, the plurality of high-power voltage regulators 114 is positioned adjacent to the base die 110. Each high power voltage regulator of the plurality of low power voltage regulators 114 may operate between 3.3V to 20V.

In an aspect of the present disclosure, each high-power voltage regulator of the plurality of high-power voltage regulators may be a first size and may have a first switching frequency.

In an aspect of the present disclosure, each low-power voltage regulator of the plurality of low-power voltage regulators may be a second size and may have a second switching frequency. In an aspect of the present disclosure, the first size may be smaller than the second size. In an aspect of the present disclosure, the first switching frequency of each high-power voltage regulator is higher than the second switching frequency of each low-power voltage regulator. In an aspect of the present disclosure, the size of a voltage regulator can be reduced by increasing the operating frequency of the voltage regulator.

In an aspect, the GPU and CPU suffer huge amounts of power loss on the PCB 102 as the current drawn by core rails is very high. This can be addressed by reducing the current drawn from the PCB 102 to lower values by increasing the operating voltage of the rail to a higher value for the same amount of power consumption. In an aspect, the conventional voltage regulator for the high current rails on the PCB 102 is removed and the PCB 102 operates at the input voltage without any buck operation. The buck operation is carried out on the package substrate 104 by placing the high power voltage regulator on the package substrate 104 instead. To reduce the power loss on PCB 102, the power is supplied to package substrate 104 at a high voltage (e.g., 20V), which reduces the current requirement from the PCB 102 for the same amount of power consumed by the chip, and the voltage conversion is done on the package by placing a high-frequency voltage regulator on the package substrate 104. This reduces the power loss, heat dissipation, and the number of capacitors on the PCB.

In an aspect of the present disclosure, the printed circuit board 102 operates at an input voltage. In an aspect of the present disclosure, a bucking operation is conducted by the plurality of high-power voltage regulator 114 on the package substrate 104.

In an aspect of the present disclosure, the semiconductor device 100 may include a capacitor 120 disposed on the package substrate to control a ripple voltage of the package substrate. The capacitor 120 may be disposed adjacent to the plurality of high power voltage regulators 114.

In an aspect of the present disclosure, the semiconductor device 100 may include a top die 116. In an aspect, the top die 116 may be made from any suitable semiconductor, such as silicon or gallium arsenide. The top die 116 may be a semiconductor die, a chip, or a set of chiplets, e.g., a system-on-chip (SOC), a platform controller hub (PCH)/chipset, a memory device, a field programmable gate array (FPGA) device, a central processing unit (CPU), or a graphic processing unit (GPU).

In an aspect of the present disclosure, the semiconductor device 100 may include a plurality of solder bumps 118. The plurality of solder bumps 118 may be disposed between the base die 110 and the top die 116. In an aspect, the plurality of solder bumps 118 may facilitate an electrical connection between the top die 116 and the base die 110.

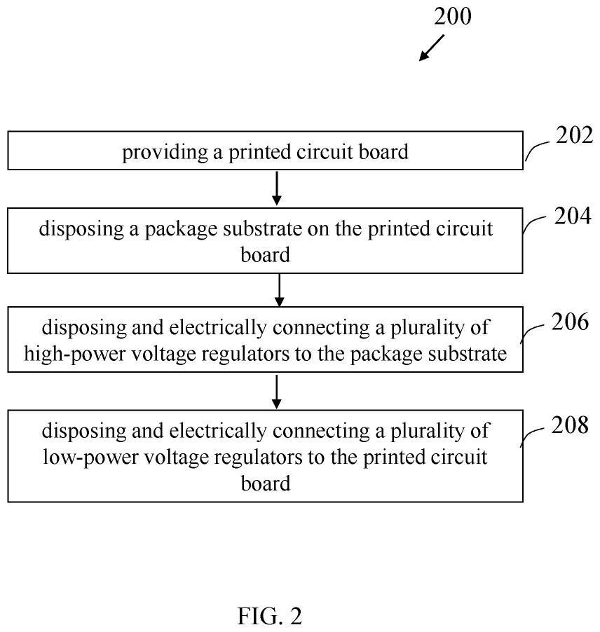

FIG. 2 shows a flow chart illustrating a method of forming a semiconductor device according to an aspect of the present disclosure.

As shown in FIG. 2, there may be a method 200 of forming a device. In the method 200, a first operation 202 may include providing a printed circuit board. A second operation 204 may include disposing a package substrate on the printed circuit board. A third operation 206 may include disposing and electrically connecting a plurality of high-power voltage regulators to the package substrate. A fourth operation 208 may include disposing and electrically connecting a plurality of low-power voltage regulators to the printed circuit board.

It will be understood that the above operations described above relating to FIG. 2 are not limited to this particular order. Any suitable, modified order of operations may be used.

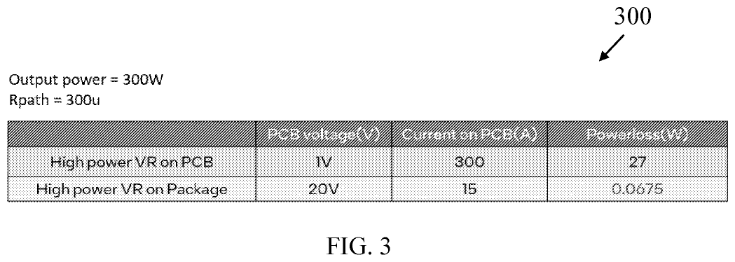

FIG. 3 shows a power loss table of a semiconductor device according to an aspect of the present disclosure.

In Table 300, when the output power is 300 W and the resistance is 300 u Ω, for conventional cases with high power VR on a PCB, the PCB voltage is 1V, the current on the PCB is 300 A and the power loss is 27 W. For an aspect disclosed herein, when the high power VR is on the package substrate instead of the PCB, the PCB voltage can be a high voltage such as 20V and the current on the PCB is 15 A for the same output power of 300 W. Therefore, there is a significantly smaller power loss of 0.0675 W compared to conventional cases.

Aspects of the present disclosure may be implemented into a system using any suitable hardware and/or software.

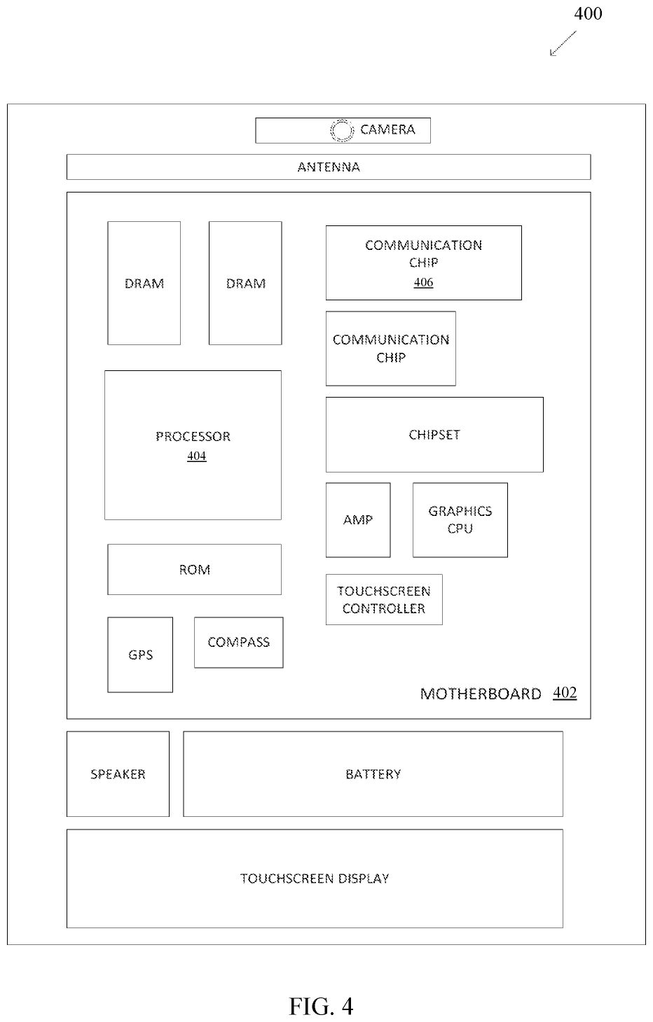

FIG. 4 schematically illustrates a computing device 400 that may include a semiconductor device as described herein, in accordance with some aspects.

As shown in FIG. 4, the computing device 400 may house a board such as a motherboard 402. The motherboard 402 may include a number of components, including but not limited to a processor 404 and at least one communication chip 406. The processor 404 may be physically and electrically coupled to the motherboard 402. In some implementations, the at least one communication chip 406 may also be physically and electrically coupled to the motherboard 402. In further implementations, the communication chip 406 may be part of the processor 404.

Depending on its applications, the computing device 400 may include other components that may or may not be physically and electrically coupled to the motherboard 402. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth). In another aspect, the processor 404 of the computing device 400 may be packaged in a semiconductor package, as described herein, and/or other semiconductor devices may be packaged together in a semiconductor package as described herein.

The communication chip 406 may enable wireless communications for the transfer of data to and from the computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some aspects they might not. The communication chip 406 may implement any of a number of wireless standards or protocols, including but not limited to Institute for Electrical and Electronics Engineers (IEEE) standards including Wi-Fi (IEEE 502.11 family), IEEE 502.16 standards (e.g., IEEE 502.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 502.16 compatible BWA networks are generally referred to as WiMAX networks, an acronym that stands for Worldwide Interoperability for Microwave Access, which is a certification mark for products that pass conformity and interoperability tests for the IEEE 502.16 standards.

The communication chip 406 may also operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 406 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 406 may operate in accordance with other wireless protocols in other aspects.

The computing device 400 may include a plurality of communication chips 406. For instance, a first communication chip 406 may be dedicated to shorter range wireless communications such as Wi-Fi and Bluetooth, and a second communication chip 406 may be dedicated to longer range wireless communications such as GPS, EDGE, GPRS, CDMA, WiMAX, LTE, Ev-DO, and others.

In various implementations, the computing device 400 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In an aspect, the computing device 400 may be a mobile computing device. In further implementations, the computing device 400 may be any other electronic device that processes data.

### EXAMPLES

Example 1 may include a device including a printed circuit board; a package substrate disposed on the printed circuit board; a plurality of high-power voltage regulators disposed on and electrically connected to the package substrate; and a plurality of low-power voltage regulators disposed on and electrically connected to the printed circuit board.

Example 2 may include the device of example 1 and/or any other example disclosed herein, for which a first size of each high-power voltage regulator of the plurality of high-power voltage regulators is smaller than a second size of each low-power voltage regulator of the plurality of low-power voltage regulators.

Example 3 may include the device of example 2 and/or any other example disclosed herein, for which a first switching frequency of each high-power voltage regulator is higher than a second switching frequency of each low-power voltage regulator.

Example 4 may include the device of example 1 and/or any other example disclosed herein, for which the printed circuit board operates at an input voltage.

Example 5 may include the device of example 4 and/or any other example disclosed herein, for which a bucking operation is conducted by the plurality of high-power voltage regulators on the package substrate.

Example 6 may include the device of example 5 and/or any other example disclosed herein, further including a capacitor disposed on the package substrate to control a ripple voltage of the package substrate.

Example 7 may include the device of example 1 and/or any other example disclosed herein, further including a base die disposed on the package substrate, for which the plurality of high-power voltage regulators is positioned adjacent to the base die.

Example 8 may include the device of example 1 and/or any other example disclosed herein, for which the plurality of low-power voltage regulators is positioned adjacent to the package substrate.

Example 9 may include a method including providing a printed circuit board; disposing a package substrate on the printed circuit board; disposing and electrically connecting a plurality of high-power voltage regulators to the package substrate; and disposing and electrically connecting a plurality of low-power voltage regulators to the printed circuit board.

Example 10 may include the method of example 9 and/or any other example disclosed herein, for which a first size of each high-power voltage regulator of the plurality of high-power voltage regulators is smaller than a second size of each low-power voltage regulator of the plurality of low-power voltage regulators.

Example 11 may include the method of example 10 and/or any other example disclosed herein, for which a first switching frequency of each high-power voltage regulator is higher than a second switching frequency of each low-power voltage regulator.

Example 12 may include the method of example 9 and/or any other example disclosed herein, further including operating the printed circuit board at an input voltage.

Example 13 may include the method of example 9 and/or any other example disclosed herein, further including conducting a bucking operation at the package substrate.

Example 14 may include the method of example 13 and/or any other example disclosed herein, further including disposing a capacitor on the package substrate to control a ripple voltage of the package substrate.

Example 15 may include the method of example 9 and/or any other example disclosed herein, further including disposing a base die on the package substrate, for which the plurality of high-power voltage regulators is positioned adjacent to the base die.

Example 16 may include the method of example 9 and/or any other example disclosed herein, for which the plurality of low-power voltage regulators is positioned adjacent to the package substrate.

Example 17 may include a device including a package substrate; a base die disposed on the package substrate; and a plurality of high-power voltage regulators disposed on and electrically connected to the package substrate in which the plurality of high-power voltage regulators are electrically connected to the base die and provides a power source for the base die.

Example 18 may include the device of example 17 and/or any other example disclosed herein, further including a printed circuit board; and a plurality of low-power voltage regulators disposed on and electrically connected to the printed circuit board, wherein the package substrate is disposed on and electrically connected to the printed circuit board.

Example 19 may include the device of example 18 and/or any other example disclosed herein, for which a first size of each high-power voltage regulator of the plurality of high-power voltage regulators is smaller than a second size of each low-power voltage regulator of the plurality of low-power voltage regulators.

Example 20 may include the device of example 19 and/or any other example disclosed herein, for which a first switching frequency of each high-power voltage regulator is higher than a second switching frequency of each low-power voltage regulator.

These and other advantages and features of the aspects herein disclosed will be apparent through reference to the following description and the accompanying drawings. Furthermore, it is to be understood that the features of the various aspects described herein are not mutually exclusive and can exist in various combinations and permutations.

It will be understood that any property described herein for a specific system or device may also hold for any system or device described herein. It will also be understood that any property described herein for a specific method may hold for any of the methods described herein. Furthermore, it will be understood that for any device, system, or method described herein, not necessarily all the components or operations described will be enclosed in the device, system, or method, but only some (but not all) components or operations may be enclosed.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

While the present disclosure has been particularly shown and described with reference to specific aspects, it should be understood by those skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a printed circuit board;
a package substrate disposed on the printed circuit board;
a plurality of high-power voltage regulators disposed on and electrically connected to the package substrate; and
a plurality of low-power voltage regulators disposed on and electrically connected to the printed circuit board.

2. The device of claim 1, wherein a first size of each high-power voltage regulator of the plurality of high-power voltage regulators is smaller than a second size of each low-power voltage regulator of the plurality of low-power voltage regulators.

3. The device of claim 2, wherein a first switching frequency of each high-power voltage regulator is higher than a second switching frequency of each low-power voltage regulator.

4. The device of claim 1, wherein the printed circuit board operates at an input voltage.

5. The device of claim 4, wherein a bucking operation is conducted by the plurality of high-power voltage regulators on the package substrate.

6. The device of claim 5, further comprising a capacitor disposed on the package substrate to control a ripple voltage of the package substrate.

7. The device of claim 1, further comprising a base die disposed on the package substrate, wherein the plurality of high-power voltage regulators is positioned adjacent to the base die and provides a power source for the base die.

8. The device of claim 1, wherein the plurality of low-power voltage regulators is positioned adjacent to the package substrate.

9. A method comprising:
providing a printed circuit board;
disposing a package substrate on the printed circuit board;
disposing and electrically connecting a plurality of high-power voltage regulators to the package substrate; and
disposing and electrically connecting a plurality of low-power voltage regulators to the printed circuit board.

10. The method of claim 9, wherein a first size of each high-power voltage regulator of the plurality of high-power voltage regulators is smaller than a second size of each low-power voltage regulator of the plurality of low-power voltage regulators.

11. The method of claim 10, wherein a first switching frequency of each high-power voltage regulator is higher than a second switching frequency of each low-power voltage regulator.

12. The method of claim 9, further comprising operating the printed circuit board at an input voltage.

13. The method of claim 9, further comprising conducting a bucking operation at the package substrate.

14. The method of claim 13, further comprising disposing a capacitor on the package substrate to control a ripple voltage of the package substrate.

15. The method of claim 9, further comprising disposing a base die on the package substrate, wherein the plurality of high-power voltage regulators is positioned adjacent to the base die.

16. The method of claim 9, wherein the plurality of low-power voltage regulators is positioned adjacent to the package substrate.

17. A device comprising:
a package substrate;
a base die disposed on the package substrate; and
a plurality of high-power voltage regulators disposed on and electrically connected to the package substrate, wherein the plurality of high-power voltage regulators are electrically connected to the base die and provides a power source for the base die.

18. The device of claim 17, further comprising:
a printed circuit board; and
a plurality of low-power voltage regulators disposed on and electrically connected to the printed circuit board, wherein the package substrate is disposed on and electrically connected to the printed circuit board.

19. The device of claim 18, wherein a first size of each high-power voltage regulator of the plurality of high-power voltage regulators is smaller than a second size of each low-power voltage regulator of the plurality of low-power voltage regulators.

20. The device of claim 19, wherein a first switching frequency of each high-power voltage regulator is higher than a second switching frequency of each low-power voltage regulator.
